(19) United States
(12) Patent Application Publication
(10) Pub. No.: US 2018/0033643 A1
(43) Pub. Date: Feb. 1, 2018

(54) METHODS AND APPARATUS FOR USING ALKYL AMINES FOR THE SELECTIVE REMOVAL OF METAL NITRIDE

(71) Applicant: APPLIED MATERIALS, INC., Santa Clara, CA (US)

(72) Inventors: Vijay Bhan SHARMA, Bharatpur (IN); Ranga Rao ARNEPALLI, Bapulapadu (IN); Prerna GORADIA, Mumbai (IN); Robert Jan VISSER, Menlo Park, CA (US)

(21) Appl. No.: 15/552,207

(22) PCT Filed: Feb. 25, 2016
(86) PCT No.: PCT/US2016/019484

§ 371 Date: Aug. 18, 2017

(30) Foreign Application Priority Data
Feb. 25, 2015 (IN) 551/DEL/2015

(51) Int. Cl. H01L 21/3213; H01L 21/311; H01L 21/683; H01L 21/02; H01L 21/306; H01L 21/67

(52) U.S. Cl. CPC H01L 21/32135; H01L 21/306; H01L 21/67109; H01L 21/6719; H01L 21/6838; H01L 21/02244; H01L 21/31144

(57) ABSTRACT

Improved methods and apparatus for removing a metal nitride selectively with respect to exposed or underlying dielectric or metal layers are provided herein. In some embodiments, a method of etching a metal nitride layer atop a substrate, includes: (a) oxidizing a metal nitride layer to form a metal oxynitride layer (MN1-xOx) at a surface of the metal nitride layer, wherein M is one of titanium or tantalum and x is an integer from 0.05 to 0.95; and (b) exposing the metal oxynitride layer (MN1-xOx) to a process gas, wherein the metal oxynitride layer (MN1-xOx) reacts with the process gas to form a volatile compound which desorbs from the surface of the metal nitride layer.

### FIELD

Embodiments of the present disclosure generally relate to methods and apparatus for using alkyl amines for the selective removal of metal nitrides.

### BACKGROUND

Metal nitride materials such as titanium nitride (TiN) and tantalum nitride (TaN) are commonly used in the semiconductor industry for many semiconductor applications, such as a masking material or as a barrier material. However, selectively removing a metal nitride masking material without harming other structures, for example exposed or underlying dielectric or metal layers, is very difficult. The problem of selectively removing a metal nitride masking material without harming other structures becomes even more difficult where solution based or plasma based approaches are not feasible and/or desirable.

Accordingly, the inventors have developed improved methods and apparatus for removing a metal nitride selectively with respect to exposed or underlying dielectric or metal layers.

### SUMMARY

Methods and apparatus for removing a metal nitride selectively with respect to exposed or underlying dielectric or metal layers are provided herein. In some embodiments, a method of etching a metal nitride layer atop a substrate includes: (a) oxidizing a metal nitride layer to form a metal oxynitride layer (MN₁₋ₓOₓ) at a surface of the metal nitride layer, wherein M is one of titanium or tantalum and x is an integer from 0.05 to 0.95; and (b) exposing the metal oxynitride layer (MN₁₋ₓOₓ) to a process gas, wherein the metal oxynitride layer (MN₁₋ₓOₓ) reacts with the process gas to form a volatile compound which desorbs from the surface of the metal nitride layer.

In some embodiments, a method of etching a titanium nitride layer atop a substrate includes: exposing a titanium nitride layer to a process gas formed by vaporizing a process solution comprising diethylamine and water, wherein the titanium nitride layer reacts with the process gas to form a volatile compound which desorbs from the surface of the titanium nitride layer.

In some embodiments, an apparatus for etching a metal nitride layer atop a substrate apparatus for etching a metal nitride layer atop a substrate includes: a reactor body comprising a processing volume to hold a liquid process solution, a body flange at a first end, and a first heater embedded within or coupled to the reactor body at a second end opposite the first end to heat the liquid process solution; a reactor lid comprising a lid flange at a first end configured to mate with the body flange; a circumferential clamp configured to clamp the reactor body to the reactor lid at the lid flange and the body flange; a vacuum chuck embedded within the reactor lid and configured to hold a substrate within the processing volume such that a metal nitride layer disposed on the substrate faces a bottom of the processing volume; a second heater embedded within or coupled to the reactor lid and configured to heat the substrate; and an exhaust system coupled to the reactor body to remove process byproducts from the processing volume.

Other embodiments and variations of the present disclosure are discussed below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. The appended drawings illustrate only typical embodiments of the disclosure and are therefore not to be considered limiting of the scope, for the disclosure may admit to other equally effective embodiments.

FIG. 1 depicts a flowchart of a method of etching a metal nitride layer atop a substrate in accordance with some embodiments of the present disclosure.

FIGS. 2A-C depicts the stages of etching a metal nitride layer atop a substrate in accordance with some embodiments of the present disclosure.

FIG. 3 depicts a cross-sectional view of an apparatus suitable to perform methods for etching a metal nitride layer atop a substrate in accordance with some embodiments of the present disclosure

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Methods and apparatus for etching a metal nitride selectively with respect to exposed or underlying dielectric or metal layers are provided herein. In some embodiments, the inventive methods described herein advantageously provide an innovative method of etching a metal nitride, utilized as a masking material, selectively with respect to exposed or underlying dielectric or metal layers, for example BLACK DIAMOND® dielectric material available from Applied Materials, Inc. of Santa Clara, Calif. (hereinafter “Black Diamond” or “BD”) or silicon dioxide layers (e.g. SiOx). The inventive methods described herein may also be used in other semiconductor manufacturing applications where etching a metal nitride may be necessary. In some embodiments, an amine-based solution is vaporized and applied to a metal nitride material to selectively etch the metal nitride material from the top of structures without harming, for example, underlying or exposed Black Diamond, silicon dioxide, and/or copper (Cu) structures.

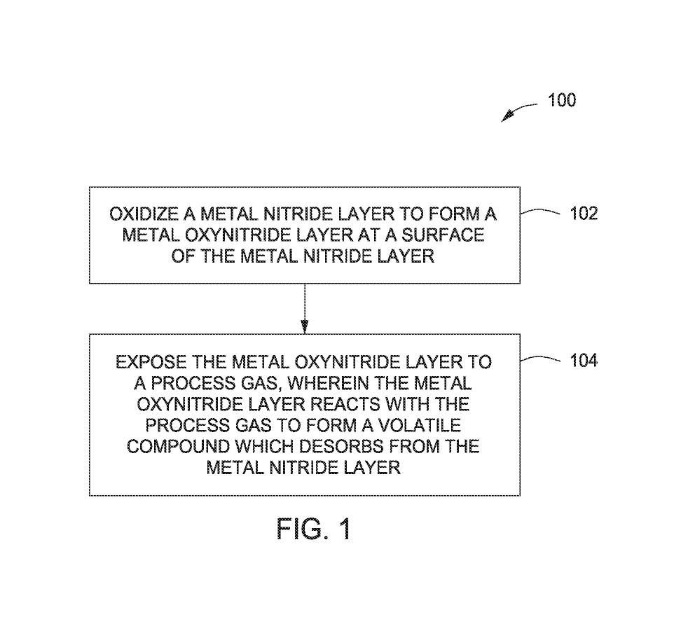

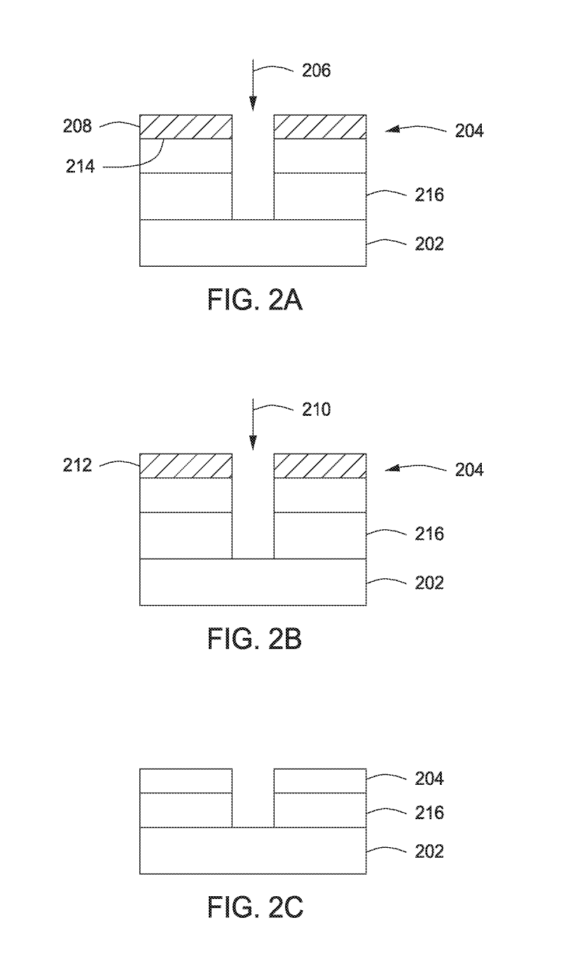

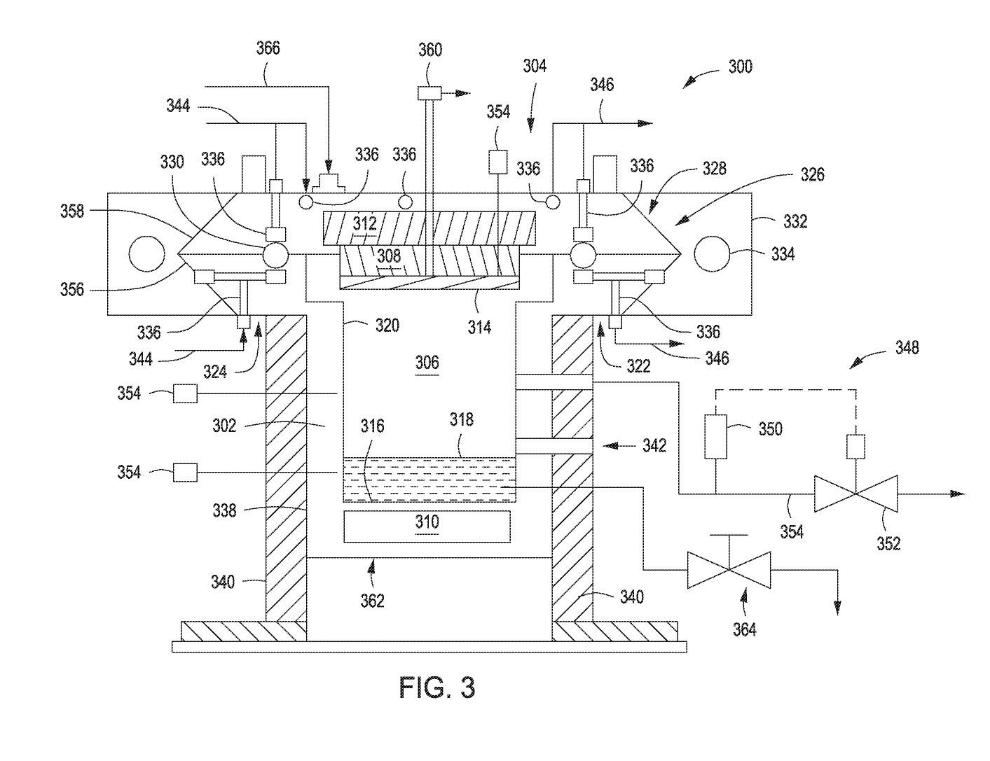

FIG. 1 is a flow diagram of a method 100 of etching a metal nitride layer atop a substrate in accordance with some embodiments of the present disclosure. FIGS. 2A-2C are illustrative cross-sectional views of the substrate during different stages of the processing sequence of FIG. 1 in accordance with some embodiments of the present disclosure. The inventive methods may be performed in a suitable reactor vessel, such as the reactor vessel discussed below with respect to FIG. 3.

FIG. 3 depicts a cross-sectional view of a reactor vessel 300 suitable for performing method 200. The reactor vessel 300 is a closed loop controlled system using materials for the wetted parts of the reactor vessel 300 that are compatible with chemicals utilized in method 200 described below. The reactor vessel 300 depicted in FIG. 3 comprises a reactor body 302 and a reactor lid 304. The reactor body 302 and the reactor lid 304 comprise suitable openings for the addition of sensors, power, and vacuum inputs as described below. The reactor body 302 comprises a processing volume 306. The processing volume 306 holds a suitable liquid process solution 318 used in the method 100 described below. In some embodiments, the processing volume 306 can hold up to about 200 to about 300 ml of a suitable liquid process solution 318.

The reactor body 302 and the reactor lid are made of material suitable for withstanding the temperature and pressures utilized in the method 200 described below. In some embodiments, the reactor body 302 and the reactor lid are made of stainless steel (SST) material coated with, for example Teflon or Magnaplate 10K. The coating can be selected based on the compatibility with the chemicals, temperatures, and pressures utilized in the method 200. The reactor body 302 comprises a body flange 322 at a first end 324. The reactor lid 304 comprises a lid flange 326 at a first end 328 configured to mate with the body flange 322. The body flange 322 is clamped with the lid flange 326 and having a leak proof O-ring 330 seal. The body flange 322 has a chamfered back-surface 356. The lid flange 326 has a chamfered back-surface 358. The body flange 322 and the lid flange 326 are mated by a circumferential clamp 332 tightened by a bolt 334 around the chamfered back-surfaces 356, 358.

Cooling channels 336 are added in the vicinity of the O-ring 330 to protect the O-ring 330 from high temperatures. Cooling channels 336 are also provided on the top of the reactor lid 304 to maintain the outer reactor lid 304 temperature below about 70° C. for safety purposes. Suitable inlets 344 and outlets 346 are coupled to the cooling channels 336 to supply and remove a cooling fluid such as water from the cooling channels 336. The outside walls 338 of the reactor body 302 are covered with an insulation jacket 340 to avoid condensation of process gases and protection from high temperature surfaces.

A vacuum chuck 308, coupled to a vacuum source 360, is embedded within the reactor lid 304 and configured to hold the substrate 314 within the processing volume 306. The vacuum chuck 308 holds the substrate 314 such that the metal nitride layer disposed on the substrate 314 faces the bottom 316 of the processing volume 306.

The liquid process solution 318 within the processing volume 306 is heated using, for example, a first heater 310 embedded within or coupled to the reactor body 302 at a second end 362. The first heater 310 is coupled to a suitable power supply (not shown). The first heater 310 heats the liquid process solution 318 to a temperature sufficient to vaporize the solvent.

In some embodiments, the substrate 314 is heated using, for example, a second heater 312 embedded within or coupled to the reactor lid 304. The second heater 312 is coupled to a suitable power supply (not shown). In some embodiments, the first heater 310 and the second heater 312 may be at the same temperature. In some embodiments, the first heater 310 and the second heater 312 may be at different temperatures. In some embodiments, the first heater may be at a temperature of about 25 degrees Celsius to about 300 degrees Celsius. In some embodiments, the second heater is at a higher temperature than the first heater to avoid condensation of vapors onto the substrate 314. In some embodiments, the second heater 312 is at a temperature that is about 10 to about 15 degrees greater than the first heater temperature.

In some embodiments, the reactor lid 304 is clamped to a top portion of the reactor body 302 to seal the processing volume 306. In some embodiments, the reactor body 302 is also heated using for example heating coils within the reactor body 302. Heating the reactor body 302 prevents condensation of vapors onto the interior surface walls 320 of the processing volume 306.

The liquid process solution 318 is injected inside the processing volume 306 through an opening 342 in the reactor body 302. A manual valve 364 is used to drain out the liquid process solution 318 from the processing volume 306.

A closed loop controlled exhaust system 348 coupled to the reactor body 302 takes a feedback from a pressure transducer 350 setting to trigger a pneumatic valve 352 to releases byproducts of the method 200 to, for example a scrubber, via the overpressure line 354. A temperature loop feedback is maintained by thermocouples 354 & an over temperature switch 366 with heater controller.

The method 100 begins at 102, and as depicted in FIG. 2A, by oxidizing a metal nitride layer 204 atop a substrate 202. The substrate 202 may be any suitable substrate, such as a semiconductor wafer. Substrates having other geometries, such as rectangular, polygonal, or other geometric configurations may also be used. In some embodiments, the substrate 202 may include a first layer 216. The first layer 216 may be a base material of the substrate 202 (e.g., the substrate itself), or a layer formed on the substrate. For example, in some embodiments, the first layer 216 may be a layer suitable for forming a feature within the first layer 216. For example, in some embodiments, the first layer 216 may be a dielectric layer, such as silicon oxide (SiO2), silicon nitride (SiN), a low-k material, or the like. In some embodiments, the low-k material may be carbon-doped dielectric materials (such as carbon-doped silicon oxide (SiOC), BLACK DIAMOND® dielectric material available from Applied Materials, Inc. of Santa Clara, Calif., or the like), an organic polymer (such as polyimide, parylene, or the like), organic doped silicon glass (OSG), fluorine doped silicon glass (FSG), or the like. In some embodiments, the first layer 216 may be a copper layer.

In some embodiments, the metal nitride layer 204 is titanium nitride (TiN) or tantalum nitride (TaN). In some embodiments, the metal nitride layer 204 is deposited using any suitable deposition process known in the semiconductor manufacturing industry, such as a physical vapor deposition (PVD) process or a chemical vapor deposition (CVD) process. In some embodiments, the metal nitride layer may be a masking layer used for forming features, such as vias or trenches in underlying layers. Oxidation of the metal nitride layer 204 forms a metal oxynitride layer (MN₁₋ₓOₓ) 208 at a surface 214 of the metal nitride layer 204, where M is one of titanium or tantalum and x is an integer from 0.05 to 0.95.

In some embodiments as depicted in FIG. 2A, the metal nitride layer 204 is oxidized by exposing the metal nitride layer 204 to an oxygen-containing gas 206. In some embodiments, the oxygen containing gas is oxygen (O₂) gas or ozone (O₃) gas or combination thereof. In some embodiments, the oxygen-containing gas 206 is provided at a flow rate of about 2 sccm to about 20 sccm for about 2 to about 30 seconds.

Next, at 104 and as depicted in FIG. 2B, the metal oxynitride layer (MN₁₋ₓOₓ) 208 is exposed to a process gas 210. The reaction of the process gas 210 and the metal oxynitride layer (MN₁₋ₓOₓ) 208 forms a volatile compound 212 atop the metal nitride layer 204 which desorbs from the surface 214 of the metal nitride layer 204. The volatile compound 212 desorbs from the surface 214 of the metal nitride layer 204 at the temperature at which the process gas 210 is formed, accordingly a separate anneal process is unnecessary to desorb the volatile compound 212. In some embodiments, the process gas 210 is produced by heating a liquid process solution within the reactor vessel 300 to at least the boiling point of the liquid process solution. In some embodiments, the process solution comprises an etchant precursor of secondary amines having the formula R₁R₂NH wherein R₁ and R₂ can be an alkyl group such as methyl, ethyl, propyl, or butyl. In some embodiments, the etchant precursor is diethylamine, tert-butylamine, ethyldenediamine, triethylamine, dicyclohexylamine, hydroxylamine, dipropylamine, dibutylamine, butylamine, isopropylamine, or propylamine.

In some embodiments, the liquid process solution is heated to a temperature of at least the boiling point of the liquid process solution or in some embodiments to a temperature of at least above the boiling point of the liquid process solution. A person of ordinary skill in the art will understand that the maximum temperature to which the liquid process solution is heated is limited by the decomposition temperature of the selected etchant precursor molecule. For example in some embodiments, the process solution comprising diethylamine, which has a boiling point of about 55 degrees Celsius, is heated to a temperature of about 80 to about 175 degrees Celsius. For example, in some embodiments, the process solution comprising dicyclohexylamine, having a boiling point of about 255 degrees Celsius, is heated to a temperature of up to about 300 degrees Celsius. The inventors have also observed that increasing the volume of the etchant precursor, for example from about 5 ml to about 30 ml, and utilizing higher temperatures to vaporize the process solution (though still limited by decomposition temperature of the selected etchant precursor molecule), results in an increase in the pressure within the reactor vessel 300 which improves the etch rate of the metal nitride layer 204. The inventors have observed that a pressure range of about 1 atmosphere (atm) to about 10 atm, for example about 7 atm improves the etch rate of the metal nitride layer 204. In some embodiments, the metal oxynitride layer (MN₁₋ₓOₓ) 208 is exposed to the process gas 210 for about 10 to 1200 seconds, for example for about 10 to about 300 seconds, for example for about 60 to about 1200 seconds.

In some embodiments, the oxidation of the metal nitride layer 204 is done within the reactor vessel 300 without exposure to the oxygen-containing gas as described above (i.e., in-situ oxidation). In in-situ oxidation embodiments, the metal nitride layer is not exposed to an initial oxygen-containing gas. Instead, the liquid process solution comprises a mixture of the etchant precursor and water. In some embodiments, the liquid process solution consists of, or consists essentially of, a mixture of the etchant precursor and water. In some embodiments, the liquid process solution comprises about 0.1 wt. % to about 5 wt % of water and the balance etchant precursor. The inventors have observed that the addition of water within the liquid process solution the process gas 210 shown in FIG. 2B can advantageously oxidize and etch the metal nitride layer 204 in a single step and furthermore improve the etch rate of the metal nitride layer 204 as compared to an initial oxidation of the metal nitride layer 204 oxidation via exposure to the oxygen-containing gas. For example, performing an in-situ oxidation results in an metal nitride layer 204 etch rate of about 3 to 4 angstroms/minute, whereas a separate oxidation step results in a lower metal nitride layer 204 etch rate.

In some embodiments, the method 100 can be repeated to etch the metal nitride layer 204 to a predetermined thickness. For example, in some embodiments, the method 100 is repeated to completely, or substantially completely, etch the metal nitride layer 204 without damaging the underlying first layer 216.

While the foregoing is directed to embodiments of the present disclosure, other and further embodiments of the disclosure may be devised without departing from the basic scope thereof.

1. A method of etching a metal nitride layer atop a substrate, comprising:
(a) oxidizing a metal nitride layer to form a metal oxynitride layer (MN₁₋ₓOₓ) at a surface of the metal nitride layer, wherein M is one of titanium or tantalum and x is an integer from 0.05 to 0.95; and
(b) exposing the metal oxynitride layer (MN₁₋ₓOₓ) to a process gas, wherein the metal oxynitride layer (MN₁₋ₓOₓ) reacts with the process gas to form a volatile compound which desorbs from the surface of the metal nitride layer.

2. The method of claim 1, further comprising:
repeating (a)-(b) to etch the metal nitride layer to a predetermined thickness.

3. The method of claim 1, wherein the metal nitride layer is oxidized prior to exposing the metal oxynitride layer (MN₁₋ₓOₓ) to the process gas.

4. The method of claim 3, wherein the metal nitride layer is oxidized via exposing the metal nitride layer to an oxygen-containing gas.

5. The method of claim 4, wherein the oxygen-containing gas comprises oxygen (O₂) gas or ozone (O₃) gas.

6. The method of claim 1, wherein exposing the metal oxynitride layer (MN₁₋ₓOₓ) to a process gas further comprises heating a liquid process solution to at least a boiling point of the liquid process solution.

7. The method of claim 6, wherein the liquid process solution comprises an etchant precursor, and wherein the etchant precursor comprises diethylamine, tert-butylamine, ethyldenediamine, triethylamine, dicyclohexylamine, hydroxylamine, dipropylamine, dibutylamine, butylamine, isopropylamine, or propylamine.

8. The method of claim 1, wherein the metal nitride layer is oxidized concurrent with exposing the metal oxynitride layer (MN₁₋ₓOₓ) to the process gas.

9. The method of claim 8, wherein exposing the metal oxynitride layer (MN₁₋ₓOₓ) to the process gas further comprises heating a liquid process solution comprising a mixture of an etchant precursor and water to at least a boiling point of the liquid process solution.

10. The method of claim 9, wherein the etchant precursor comprises diethylamine, tert-butylamine, ethyldenediamine, triethylamine, dicyclohexylamine, hydroxylamine, dipropylamine, or dibutylamine.

11. The method of claim 1, further comprising exposing the metal oxynitride layer (MN₁₋ₓOₓ) to the process gas at a pressure of about 1 atmosphere to about 10 atmosphere and for about 60 to about 1200 seconds.

12. The method of claim 1, wherein exposing the metal oxynitride layer (MN₁₋ₓOₓ) to the process gas further comprises exposing the metal oxynitride layer (MN₁₋ₓOₓ) to the process gas within a reactor vessel comprising a reactor body and a reactor lid.

13. The method of claim 12, wherein the reactor body comprises a processing volume configured to hold a liquid process solution.

14. The method of claim 13, wherein the reactor lid comprises a vacuum chuck coupled to the reactor lid and configured to hold the substrate within the processing volume, and wherein the reactor body comprises a first heater configured to heat the liquid process solution to a temperature sufficient to vaporize the liquid process solution and the reactor lid comprises a second heater to heat the substrate.

15. An apparatus for etching a metal nitride layer atop a substrate, comprising:
a reactor body comprising: a processing volume to hold a liquid process solution, a body flange at a first end, and a first heater embedded within or coupled to the reactor body at a second end opposite the first end to heat the liquid process solution;
a reactor lid configured to mate with the body flange;
a clamp configured to clamp the reactor body to the reactor lid;
a vacuum chuck embedded within or coupled to the reactor lid and configured to hold a substrate within the processing volume such that a working surface of the substrate faces a bottom of the processing volume;
a second heater embedded within or coupled to the reactor lid and configured to heat the substrate; and
an exhaust system coupled to the reactor body to releases process byproducts from the processing volume.

16. The apparatus of claim 15, wherein the liquid process solution comprises an etchant precursor comprising diethylamine, tert-butylamine, ethyldenediamine, triethylamine, dicyclohexylamine, hydroxylamine, dipropylamine, dibutylamine, butylamine, isopropylamine, or propylamine.

17. The apparatus of claim 15, wherein the first heater is sufficient to heat to a temperature of about 25 degrees Celsius to about 300 degrees Celsius.

18. The apparatus of claim 15, wherein the second heater is sufficient to heat to a temperature of about 10 to about 15 degrees greater than the first heater.

19. The apparatus of claim 15, wherein the apparatus is a closed-loop system.

20. The apparatus of claim 15, further comprising an insulation jacket disposed around outside walls of the reactor body.
